(19) United States
(12) Patent Application Publication
(10) Pub. No.: US 2008/0039332 A1
(43) Pub. Date: Feb. 14, 2008

(54) Method and System for the Production of Superconducting Inductive Components Comprising Thin Layers, and Devices Containing Such Components

(75) Inventors: Pierre-Ernest Bernstein, Villiers Le Sec (FR); Jean-Francois Maurice Hamet, Anguerny (FR); Nabil Touitou, Gieres (FR)

Correspondence Address: GREER, BURNS & CRAIN, 300 S WACKER DR, 25TH FLOOR, CHICAGO, IL, 60606, US

(73) Assignee: CENTRE NATIONAL DE LA RECHERCHE SCIENTIFIQUE, F-75794 Paris, Cedex 16 (FR)

(21) Appl. No.: 10/566,070

(22) PCT Filed: Jul. 16, 2004
(86) PCT No.: PCT/FR04/01873

§ 371 Date: Jan. 26, 2006

(30) Foreign Application Priority Data
Jul. 28, 2003 (FR) 03/09212

(51) Int. Cl. H01L 39/12; H01F 6/06; H01Q 1/36; H01Q 21/00; H03H 7/32

(52) U.S. Cl. 505/201; 505/210; 505/211; 505/410; 505/470; 333/138; 333/167; 343/722; 427/62; 216/13

(57) ABSTRACT

A method for producing a superconducting inductive component having at least two plots, the component including at least one line segment incorporating at least one plot of the component, the line segment constituting a conducting or superconducting layer within a stack of alternately superconducting and insulating films.

The present invention relates to a method for producing superconducting inductive components in thin layers. It also relates to a production system implementing this method, as well as to devices including such components.

This invention pertains to the field of superconducting electric and electronic components for the telecommunications and electric energy sectors.

The production of superconducting inductive components in thin layers is generally carried out by depositing a superconducting film, generally by vacuum methods such as cathode sputtering or pulsed laser ablation, then the definition by photolithographic etching of one or more turns. In this technique the dimension of the device increases with the value of its inductance.

A practical example of production consists in a coil comprising 5 spires of which the external diameter is 15 mm, with tracks of width 0.4 mm spaced by 0.3 mm exhibiting an inductance of 2.12 pH, which is described in the thesis paper submitted by Jean-Christophe Ginefri on Dec. 16th, 1999 at the University of Paris XI and entitled “Antenne de surface supraconductrice miniature pour I'imagerie RMN á 1,5 Tesla” (“Miniature superconducting surface antenna for NMR imaging at 1.5 Tesla.”)

The technique described above has two main drawbacks:

the area occupied by each inductive component is large. For example, the component described in the previous paragraph occupies an area of more of 700 mm²:

if the component is integrated in a circuit, it is often necessary to connect the end of the inside spire to a superconducting line. This involves a complex process comprising, after the deposit and the etching of the turns:
a) the deposit and the etching of an insulating film,
b) the deposit and the etching on this insulator of a second superconducting film having properties similar to those of the first film. This last step is particularly delicate as it is necessary to carry out an epitaxy resuming, a technique which is difficult to control. There are other methods making it possible to deposit a coil in thin layers, but the difficulties in carrying them out are identical to those described here.

The purpose of the present invention is to overcome these drawbacks by proposing a production method that is simpler and less costly than present day methods.

This objective is achieved with a method of producing a superconducting inductive component in the form of one or more line segments having an area of the order of a few hundreds of a square micron comprising a stack of alternately superconducting and insulating films.

At least one of these line segments then incorporates at least one part constituting one of the plots of the component.

In particular, this method allows the production of a superconducting inductive component having at least two plots, this component comprising at least one line segment incorporating at least one plot of the component, this line segment constituting a conducting or superconducting layer within at least one stack of alternately superconducting and insulating films.

It is thus possible to make use of collective manufacturing methods and that can be automated, using known and widespread techniques of depositing thin layers and of etching, which contributes to a substantial reduction of manufacturing costs.

In a preferred embodiment of the invention, each film constituting the stack is perfectly crystallized. The device is dimensioned such that that in the working conditions it is in the Meissner state, that is to say in the state in which it does not exhibit measurable dissipation in direct current.

The proposed device may be produced from any pair of materials making it possible to produce a stack of alternately superconducting and insulating films below a temperature called the critical temperature. Several methods may be envisaged for the manufacture of superconducting circuits incorporating the invention.

A first method of manufacture comprises the following steps:
1) deposit of a superconducting film
2) deposit of the stack of alternately superconducting and insulating films
3) etching of all of the deposited films, for example in the form of a simultaneous etching of the stack and of the superconducting film,
4) selective etching of the stack, carried out in such a way that the latter only remains at the locations where an inductive component is to be implanted.

A second method of manufacture having the following steps may also be used:
1) deposit of a superconducting film
2) deposit of the stack of alternately superconducting and insulating films
3) selective etching of the stack, carried out in such a way that the latter only remains at the locations where an inductive component is to be implanted.
4) etching of the remainder of the circuit.

A third possible method comprises the following steps:
1) deposit of a superconducting film
2) etching of the superconducting film
3) deposit of the stack of alternately superconducting and insulating films
4) selective etching of the stack, carried out in such a way that the latter only remains at the locations where an inductive component is to be implanted.

A fourth possible method comprises the following steps:
1) deposit of the stack of alternately superconducting and insulating films
2) selective etching of the stack, carried out in such a way that the latter only remains at the locations where an inductive component is to be implanted.
3) connection of the inductive components thus produced with the remainder of the circuit by superconducting or non-superconducting connections.

According to another aspect of the invention, a system is proposed for producing a superconducting inductive component in the form of one or more line segments comprising a stack of alternately superconducting and insulating films, implementing the method according to the invention.

In a particular form of the invention, this production system comprises:

means for depositing a superconducting film on a substrate,

means for depositing on the superconducting film a stack of alternately superconducting and insulating films, and

means for etching all of the deposited films, these means being arranged in such a way that they only remain at the locations where an inductive component is to be implanted.

According to yet another aspect of the invention, there is proposed an antenna device comprising an electronic circuit including a superconducting inductive component produced by the method according to the invention.

Still within the context of the present invention, there is proposed a delay line device comprising an inductive component in serie and a capacitive component in parallel downstream of said inductive component, characterized in that the inductive component is a superconducting inductive component produced by the method according to the invention.

Delay lines according to the invention can be used in a phase shift radar device comprising a plurality of antennas each comprising an electronic circuit including a delay line according to the invention, this delay line being arranged such that each of said antennas transmits a signal the phase of which is shifted with respect to that of the near antennas.

Also within the context of the present invention, there is proposed an electronic frequency filtering device comprising an electronic circuit including a superconducting inductive component produced by the method according to the invention.

It can for example be a high-pass filter comprising an inductive component in parallel and a capacitive component in serie downstream of said inductive component, where this inductive component is a superconducting inductive component produced by the method according to the invention.

It can also be a low-pass filter comprising a capacitive component in parallel and an inductive component in serie downstream of said capacitive component, where this inductive component is a superconducting inductive component produced by the method according to the invention.

Other advantages and features of the invention will become apparent on examining the detailed description of a mode of implementation that is in no way limiting and the appended drawings in which:

FIG. 1 is a diagram of a stack E of layers C₁ and C₂ deposited on a substrate;

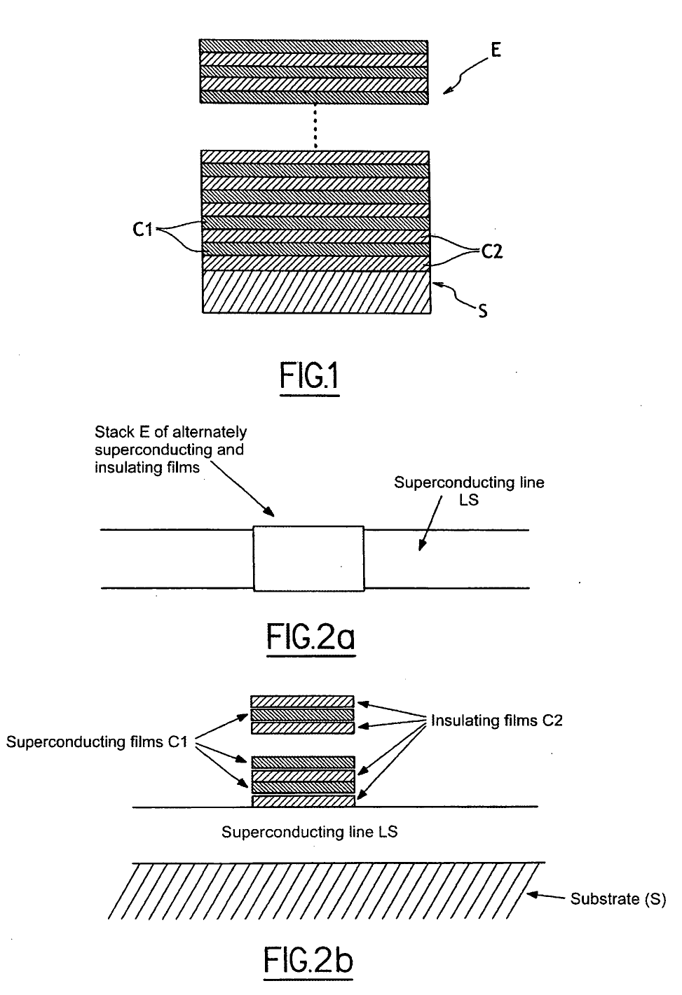

FIG. 2A is a top view of a superconducting line LS comprising an inductive component constituted by alternately superconducting C1 and insulating C2 films;

FIG. 2B is a cross-sectional view of a superconducting line LS comprising an inductive component E constituted by alternately superconducting C1 and insulating C2 films;

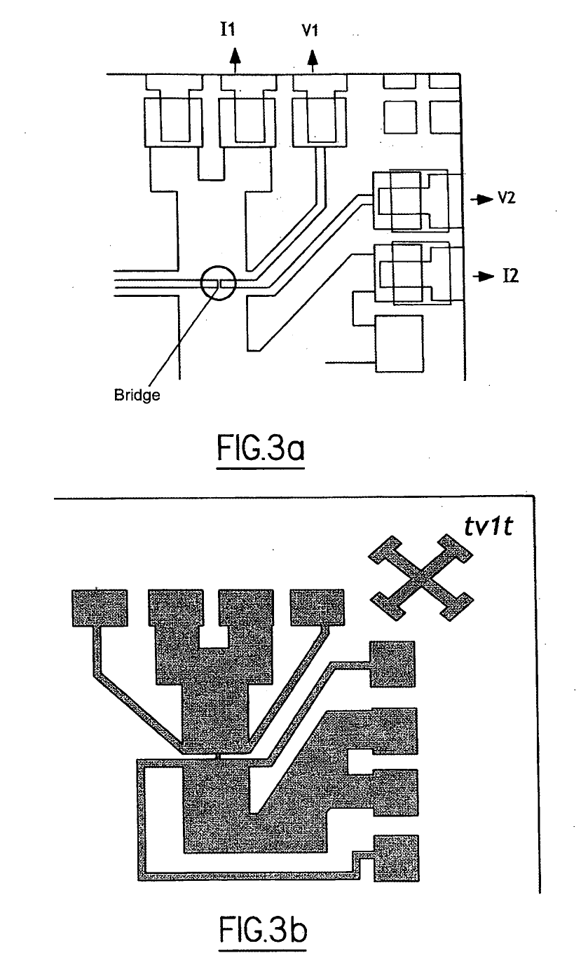

FIG. 3A is a photograph of the pattern used for the tests showing the location of the current inputs I1 and I2, the contacts VI and V2 for measuring the potential difference across the terminals of the bridge as well as the location of the latter;

FIG. 3B represents the photolithographic etching mask used for producing the test pattern of FIG. 3A;

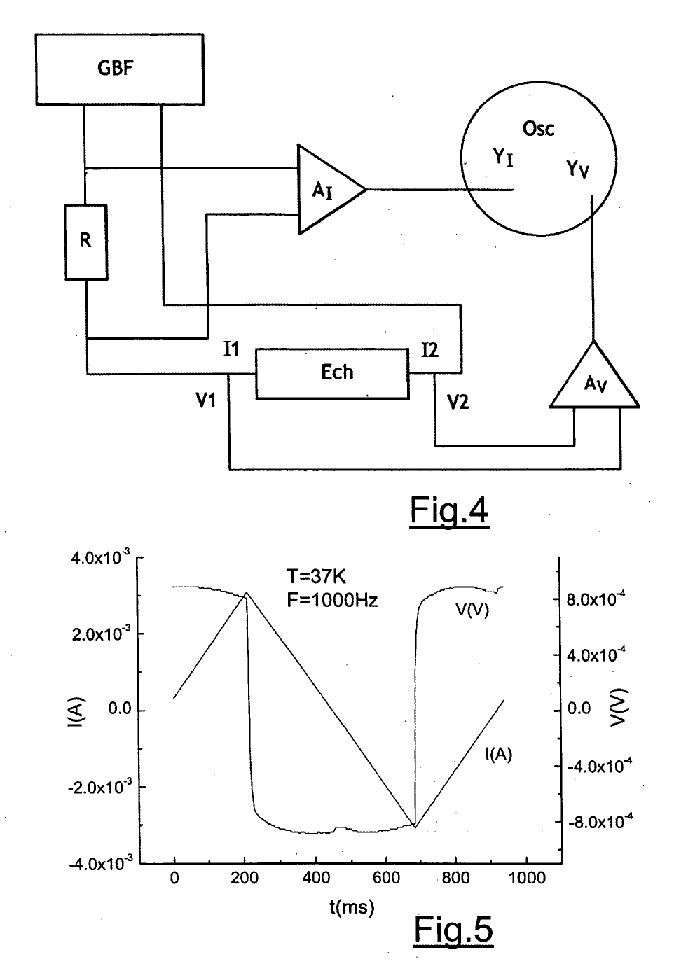

FIG. 4 is a block diagram of the measuring device used for characterizing a superconducting inductive component according to the invention;

FIG. 5 illustrates a potential difference measured between the contacts V1 and V2 (solid lines) when a saw tooth current at a frequency of 1000 Hz (dotted line) circulates in the sample;

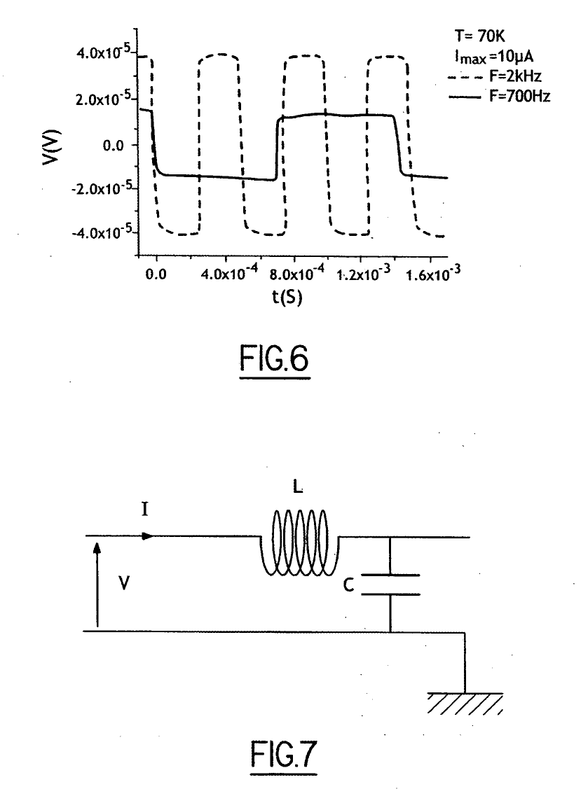

FIG. 6 shows a comparison of the potential differences measured between the contacts V1 and V2 when two saw tooth currents of the same amplitude Imax=10 microamperes but of different frequencies circulate in the sample;

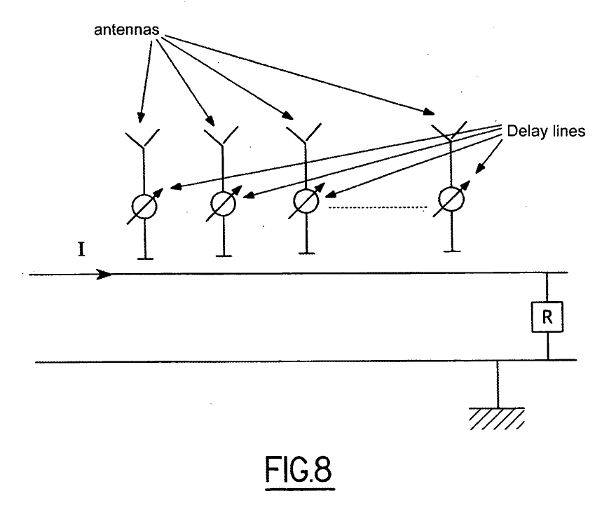

FIG. 7 illustrates a delay line implementing a superconducting inductive component according to the invention; and

FIG. 8 is a diagram showing the principle of a phase shift antenna;

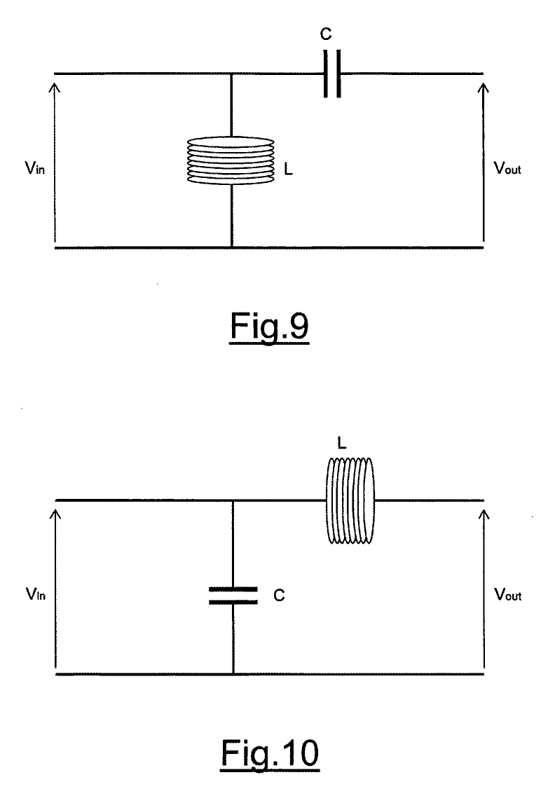

FIG. 9 is a diagram showing the principle of a high pass filter;

FIG. 10 is a diagram showing the principle of a low pass filter.

The principle used in the production method according to the invention is a stack E of alternately superconducting C1 and insulating C2 thin films deposited on a substrate S, with reference to FIG. 1, or on a superconducting line LS. It is determinant that the films C2 be strictly insulating and that growth defects do not put two adjacent superconducting films in contact.

In a preferred embodiment of the invention, the first film deposited in order to form the stack E is insulating as indicated on FIG. 1.

The integration of inductive components in a superconducting circuit may be carried out in the way shown in FIGS. 2A and 2B using the techniques of depositing thin films well known to a person skilled in that art, for example laser ablation, radio-frequency cathode sputtering, evaporation under vacuum, chemical deposit in the vapour phase and, in general, any depositing technique making it possible to obtain thin layers.

It should be noted that in this particular version of the method according to the invention, corresponding to FIGS. 2A and 2B, a superconducting film L1 deposited on a substrate S, once etched, constitutes a superconducting line LS on which is placed the inductive stack E.

In a particular example of production according to the invention, given in a non-limiting manner, the materials chosen are the compounds YBₐ₂CU₃O_{7-δ} for the superconducting films and LaAIO₃ for the insulating films. The thicknesses are 10 nm (10⁻⁸ m) for the superconducting films and 4 nm (4.10⁻⁹ m) for the insulating films. 14 pairs of films were deposited.

After depositing, the films were etched in such a way as to obtain the pattern shown in FIG. 3A in which the metallized contacts I1, I2 can be seen which enable to bring the current into the sample and those which enable to measure the voltages V1 and V2 at the terminals of the central element, called the bridge, of the pattern. As a non-limiting indication, the size of the bridge is 10 μm×20 μm.

The measuring device used for characterizing the samples of superconducting inductive components according to the invention, shown in FIG. 4, comprises a low frequency generator GBF creating a currant that is variable over time I(t) which passes through the resistor R and the sample Ech via the contacts I1 and I2. The potential difference across the plots of the resistor R is amplified by a differential amplifier AI and applied to an input YI of the oscilloscope Osc. It enables to know the intensity I(t) of the current passing through the sample. The potential difference across the plots of the sample is taken at V1 and V2, amplified by the amplifier Av and applied to the input Yv of the oscilloscope Osc.

FIG. 5 shows the signals collected at YI and Yv when the sample is at a temperature of 37K. In the present case, the sample was placed in a liquid helium cryostat, but any method enabling to obtain a temperature below the critical temperature of the studied sample is suitable.

The generator supplies a saw tooth current at a frequency of 1000 Hz. The value of the current I(t) has been plotted directly. It is observed that the potential difference of V(t) between V1 and V2 exhibits a square waveform, which indicates that V(t) is proportional to the derivative of I(t) with respect to time. This characteristic indicates that the sample is behaving as an inductive component. In FIG. 6 the signals V(t) measured at 700 Hz and 2 kHz have been plotted for a peak current value equal to 10 μA in both cases. In this figure, the solid line corresponds to the voltage measured for a current at a frequency F=700 Hz and the dotted line to that measured for a current at the frequency of F=2000 Hz.

It is observed that the ratio of the amplitudes of the signals obtained is in the ratio of the frequencies applied, which is also typical of an inductive component.

From the results shown in FIG. 6, it is deduced that the inductance of the component produced according to the invention is equal to 535 pH±10 pH. The tested components do not all have such a high inductance but values of the order of a few tens of pH have commonly been obtained with components of form identical to that described here.

The superconducting inductive components obtained by the method according to the invention may have applications in the electronic or of the electro-technical fields, in the fields of antennas and of high frequency passive components, in particular for medical imaging, or for radars and defence electronics.

In a first example of application, superconducting inductive components are used in antenna systems. Thus, in a certain number of cases, for example in medical surface magnetic resonance imaging (MRI), tuned antennas are used. An important parameter involved in the efficiency of the antenna is the quality factor which is proportional to its inductance. A superconducting antenna enables this factor to be increased as its ohmic resistance is very low. It is possible to consider obtaining a new increase in the quality factor by including a device of the type of those described here in the antenna circuit.

A particularly favourable case is that in which the antenna itself is produced from a superconducting thin film.

In another example of application, superconducting inductive components are used in delay lines. Delay lines are commonly used in all fields of electronics. The simplest form that a delay line can assume is shown in FIG. 7.

The presence in the circuit of the inductance L and of the capacitor C causes a phase difference between the voltage V and the current I. An example of use is that of phase shift radars which enable to explore the surrounding space with a system of fixed antennas. A diagram showing the principle of such a system is given in FIG. 8. In this device the main line carrying the current I is coupled with the various antennas. Each of the latter comprises a delay line in its circuit. The result of this is that each antenna transmits a signal the phase of which is shifted with respect to that of the adjacent antennas. The direction of the transmitted radiation is changed by varying this phase shift. In defence electronics, the introduction of superconducting components in electronic circuits has been studied for a long time, in particular for radars and more generally counter measures. The presence of high-inductance components of small size and the manufacture of which uses processes similar to those used for the remainder of the circuit would be an important innovation in this field.

Such inductive components which are of high performance and easy to integrate may also be used in a generic manner in most general applications of electronics, in particular for producing filtering functions of all types, for example high-pass or low-pass or band-pass. It is then possible to produce highly integrated and/or miniaturized filters.

The use of a component according to the invention in fact makes it possible to integrate an inductance of high value in a circuit of small dimensions.

As illustrated in FIGS. 9 and 10 for high-pass and low-pass filters, it is therefore possible to filter an input voltage Vᵢₙ, in order to obtain an output voltage Vₒᵤₜ, by using an inductance L. As illustrated in this example, the use of inductive components according to the invention enables to produce, in integrated circuits, filters comprising only capacitors and inductances, which are of low dissipation in comparison with filters constructed with capacitors and resistors.

The invention is not of course limited to the examples which have just been described and numerous modifications may be applied to these examples without exceeding the scope of the invention. Thus, the number of respectively insulating and superconducting films is not limited to the examples described. Moreover, the dimensions of the superconducting inductive components as well as their areas can change according to the specific applications of these components. Furthermore, the respectively superconducting and insulating films can be produced from compounds other than those proposed in the example described, provided that these compounds are satisfactory for the physical conditions required for the applications.

1. A method for producing a superconducting inductive component having at least two plots, said component comprising at least one line segment incorporating at least one plot of the component, is said line segment constituting a conducting or superconducting layer within a stack of alternately superconducting and insulating films.

2. The method according to claim 1, wherein each film constituting the stack is perfectly crystallized.

3. The method according to one of claim 1 further including a prior step of depositing an insulating film on a substrates.

4. The method according to one of claim 1, further including a prior step of depositing a superconducting film on a substrate.

5. The method according to one of claim 1, further including a prior step of depositing a superconducting film on a substrate followed by the depositing of the stack.

6. The method according to one of claim 3, further including the following steps:
a deposit of the stack of alternately superconducting and insulating films,
an etching of the stack carried out in such a way that the latter only remains at the locations where an inductive component is to be implanted.

7. The method according to claim 5, further including the following steps:
an etching of the stack carried out in such a way that the latter only remains at the locations where an inductive component is to be implanted.
an etching of the superconducting film .

8. The method according to claim 5, further including the following steps:
a simultaneous etching of the stack and of the superconducting film
an etching of the stack carried out in such a way that the latter only remains at the locations where an inductive component is to be implanted.

9. The method according to claim 1 wherein at least one of the superconducting films is produced from YBₐ₂Cu₃0_{7-δ} compounds.

10. The method according to claim 1, wherein at least one of the insulating films is made from LaA10₃ compounds.

11. A system for producing a superconducting inductive component having at least two plots, said component comprising at least one line segment incorporating at least one plot of the component, this said line segment constituting a conducting or superconducting layer within a stack of alternately superconducting and insulating films, implementing the method according to claim 1.

12. The system according to claim 11, further including:
means for depositing a stack of alternately superconducting and insulating films, and
means for etching all of the deposited films, these said means being arranged in such a way that said deposited films remain only at the locations where an inductive component is to be implanted.

13. The system according to claim 11, further including:
means for depositing a superconducting film on a substrate,
means for depositing on the superconducting film a stack of alternately superconducting and insulating films, and
means for etching all of the deposited films, these means being arranged in such a way that the film remains only at the locations where a superconducting line is to be implanted and the stack remains only at the locations where an inductive component is to be implanted.

14. An antenna device comprising an electronic circuit including a superconducting inductive component produced by the method according to claim 1.

15. The antenna device according to claim 14, wherein the antenna is produced from a superconducting thin film.

16. A delay line device comprising an inductive component in series and a capacitive component in parallel downstream of said inductive component, wherein the inductive component is a superconducting inductive component produced by the method according to claim 1.

17. A phase shift radar device comprising a plurality of antennas each comprising an electronic circuit including a delay line according to claim 16, said delay line being arranged such that each of said antennas transmits a signal whose phase is shifted with respect to that of the near antennas.

18. An electronic frequency filtering device comprising an electronic circuit including a superconducting inductive component produced by the method according to claim 1.

19. A high-pass filter device comprising an inductive component in parallel and a capacitive component in series downstream of said inductive component, wherein the inductive component is a superconducting inductive component produced by the method according to claim 1.

20. A low-pass filter device comprising a capacitive component in parallel and an inductive component in serie series downstream of said capacitive component, wherein the inductive component is a superconducting inductive component produced by the method according to claim 1.
